(19) United States
(12) Patent Application Publication
(10) Pub. No.: US 2026/0280468 A1
(43) Pub. Date: Sep. 17, 2026

(54) PASSIVATION SYSTEMS AND METHODS FOR PHOTONIC CRYSTALS

(71) Applicant: Mesodyne Inc., Somerville, MA (US)

(72) Inventors: Walker Chan, Somerville, MA (US); Cassidy Dreyfus, Cambridge, MA (US); Peter Ryan, Weston, MA (US)

(73) Assignee: Mesodyne Inc., Somerville, MA (US)

(21) Appl. No.: 19/471,757

(22) PCT Filed: Apr. 4, 2024
(86) PCT No.: PCT/US2024/022964

§ 371 Date: Oct. 2, 2025

Related U.S. Application Data
(60) Provisional application No. 63/457,179, filed on Apr. 5, 2023.

(51) Int. Cl. H02S 10/30; C23C 16/40

(52) U.S. Cl. CPC H02S 10/30; C23C 16/40

(57) ABSTRACT

The present disclosure generally relates to passivated photonic crystals, for example, for thermophotovoltaic power generation or other applications. Certain aspects are generally directed to photonic crystals comprising tantalum and/or other refractory metals passivated with a coating. In some cases, the passivating coating may comprise a ceramic material, for example, zirconia and/or hafnia. The passivating coating may prevent or reduce the exposure of the underlying tantalum and/or other refractory metals to coming into contact with water vapor. In some cases, the passivating layer separates a surrounding gas from coming into contact with the photonic crystal. Other aspects are generally related to methods of making or using passivated photonic crystals, kits including such passivated photonic crystals, or the like.

### RELATED APPLICATIONS

This application claims the benefit of U.S. Provisional Patent Application Ser. No. 63/457,179, filed Apr. 5, 2023, entitled “Passivation Systems and Methods for Photonic Crystals,” by Chan, et al., incorporated herein by reference in its entirety.

### TECHNICAL FIELD

The present disclosure generally relates to passivated photonic crystals, for example, for thermophotovoltaic power generation or other applications.

### BACKGROUND

Photonic crystals can be fabricated to exhibit specific optical properties which may be useful for applications such as thermophotovoltaic power generation. Some materials for photonic crystals, like refractory metals, have relatively low vapor pressures so that they may be used at high temperatures (e.g., 800° C.) without degrading by evaporating. Refractory metals and some other materials, however, may oxidize in the presence of water vapor when heated, wherein the oxidized material may have a significantly high vapor pressure than the reduced form of the material. The higher vapor pressure may result in the oxidized material of the photonic crystal degrading, e.g., by evaporating, which may result in a shortened lifetime of the photonic crystal. Accordingly, improvements are needed.

### SUMMARY

The present disclosure generally relates to passivated photonic crystals, for example, for thermophotovoltaic power generation or other applications. The subject matter of the present disclosure involves, in some cases, interrelated products, alternative solutions to a particular problem, and/or a plurality of different uses of one or more systems and/or articles.

Some aspects of the present disclosure are related to articles. In some cases, the article comprises a substrate comprising an IR-transparent material and defining an interior region comprising a gas containing at least 10⁻⁹ kPa of water vapor, a photonic crystal comprising tantalum, the photonic crystal being positioned at least partially within the interior region of the substrate, and a coating comprising hafnia or alumina, wherein the coating separates the water vapor in the gas from contact with the photonic crystal.

In some aspects, the article comprises a photonic crystal comprising tantalum and a coating comprising zirconia at least partially covering the tantalum.

Some aspects are related to methods. In some embodiments, the method comprises emitting radiation from a photonic crystal, passing the radiation through zirconia, hafnia, or alumina, and passing the radiation through a region having a gas containing at least 10⁻⁹ kPa of water vapor.

In another aspect, the method comprises emitting radiation from a photonic crystal, passing the radiation through a coating positioned on the photonic crystal, and passing the radiation through a region having a gas containing at least 10⁻⁹ kPa of water vapor, wherein the coating separates the water vapor in the gas from contact with the photonic crystal.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1 is a schematic illustration of a coating, a photonic crystal, and a substrate according to some embodiments; and

FIG. 2A-2B are SEM micrographs of a passivated photonic crystal comprising a photonic crystal and a coating, according to some embodiments.

### DETAILED DESCRIPTION

The present disclosure generally relates to passivated photonic crystals, for example, for thermophotovoltaic power generation or other applications. Certain aspects are generally directed to photonic crystals comprising tantalum and/or other refractory metals passivated with a coating. In some cases, the passivating coating may comprise a ceramic material, for example, zirconia and/or hafnia. The passivating coating may prevent or reduce the exposure of the underlying tantalum and/or other refractory metals to coming into contact with water vapor. In some cases, the passivating layer separates a surrounding gas from coming into contact with the photonic crystal. Other aspects are generally related to methods of making or using passivated photonic crystals, kits including such passivated photonic crystals, or the like.

Photonic crystals comprising tantalum and/or other refractory metals may exhibit useful optical properties, such as selective emissivity, which can be useful for applications like thermophotovoltaic power generation. When certain photonic crystals are exposed to water vapor, however, the photonic crystal may degrade, for instance, by evaporating. For example, in photonic crystals comprising tantalum, water vapor may oxidize the tantalum into tantalum hydroxides and/or oxyhydroxides, thereby degrading the photonic crystal, and potentially limiting its lifetime. In some cases, the photonic crystal comprising tantalum may oxidize and then degrade by evaporating, where the evaporated tantalum may redeposit elsewhere. The evaporated tantalum may redeposit in the optical pathway of the light emitted by the photonic crystal and thus may obstruct light emitted by the photonic crystal (e.g., by reflecting and/or absorbing the light). This may limit and/or eliminate the ability to use the desirable optical properties of the photonic crystal during applications like thermophotovoltaic power generation, according to some embodiments. Accordingly, as discussed herein, certain embodiments are directed to modified photonic crystals that are less susceptible to reaction with water vapor.

It may be advantageous, in some cases, to passivate the photonic crystal by applying a coating. Various coating materials are possible. The coating may be IR transparent and/or have a relatively low vapor pressure when heated. In some cases, the coating may allow passage of radiation emitted from the photonic crystal. In some embodiments, the coating materials may be resistant to degradation at high temperatures. Coatings may comprise ceramic materials, for example, hafnia and/or zirconia, and/or other materials such as those described herein. The application of coatings may prevent or minimize exposure of the tantalum and/or other refractory metals of the photonic crystal from water vapor in accordance with certain embodiments, which may extend the lifetime of the photonic crystal in some cases.

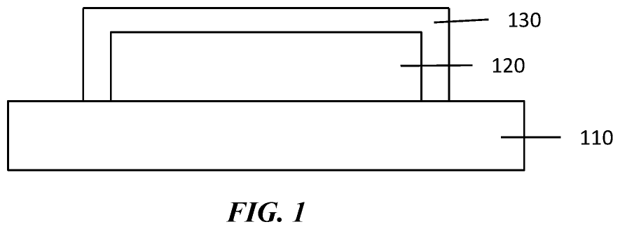

For instance, FIG. 1 is an illustrative diagram showing photonic crystal 120 disposed on top of a substrate 110. Coating 130 is further disposed on top of the photonic crystal 120. In some cases, coating 130 prevents any of photonic crystal 120 from being exposed. In this manner, coating 130 may passivate photonic crystal 120 from (e.g., prevent contact with) water vapor, which may extend the lifetime of the photonic crystal 120 during use, for example like thermophotovoltaic power generation.

The above discussion is a non-limiting example of one embodiment of the present disclosure that is generally directed to a passivated photonic crystal, e.g., one comprising tantalum and coated with zirconia and/or hafnia. However, other embodiments are also possible. Accordingly, more generally, various aspects are directed to various systems and methods for passivating a photonic crystal, for example, using a coating or placing the photonic crystal in an environment comprising little-to-no water vapor.

Photonic crystals may comprise any of a variety of suitable materials, in accordance with some embodiments. In some cases, it may be advantageous to use a photonic crystal comprising a refractory metal (e.g., niobium, molybdenum, tantalum, tungsten, osmium, iridium, ruthenium, zirconium, titanium, vanadium, chromium, rhodium, hafnium, and/or rhenium) so that the photonic crystal can withstand the relatively high temperatures without degrading, for example, by melting. In some embodiments, it may be particularly advantageous to use a photonic crystal comprising tantalum.

Photonic crystals may have a microstructure that, in some cases, has 1-dimensional periodicity. In some embodiments, the photonic crystal may have 2-dimensional periodicity. One of ordinary skill in the art would be able to determine the dimensionality of the periodicity of a photonic crystal upon inspection. For example, 1-dimensionally periodic photonic crystals include materials arranged in such a way that the index of refraction within the volume of the photonic crystal varies along one coordinate direction and does not substantially vary along two orthogonal coordinate directions. For example, a 1 dimensionally periodic photonic crystal can include two or more materials arranged in a stack within the emitter such that there is substantially no variation in the index of refraction along two orthogonal coordinate directions. 2-dimensionally periodic photonic crystals include materials arranged in such a way that the index of refraction within the volume of the photonic crystal varies along two coordinate directions and does not substantially vary along 1 coordinate direction orthogonal to the other two coordinate directions.

The periodicity of the photonic crystal may result in some of the desirable optical properties exhibited by the photonic crystal, as described above. For example, in some cases, photonic crystals can be configured such that the emittance of radiation about a cutoff wavelength changes significantly. That is, in some cases, the photonic crystal may have an emittance of radiation having a wavelength longer than the cutoff wavelength of no more than 0.4, no more than 0.3, no more than 0.2, no more than 0.1, or no more than 0.05, whereas the emittance exhibited by the photonic crystal for radiation having a shorter wavelength than the cutoff wavelength may be at least 0.5, at least 0.6, at least 0.7, at least 0.8, at least 0.9, or at least 0.95.

The cutoff wavelength, wherein the emittance of radiation from the photonic crystal is significantly different for radiation having shorter wavelengths than for radiation having longer wavelengths, may not be a discrete wavelength in radiation. That is, the cutoff wavelength may represent a band of wavelengths, in some cases, the cutoff wavelength may represent a 10 nm band. For instance, the wavelength cutoff may be for radiation having a wavelength from 1 micron to 1.01 microns. Thus, the photonic crystal exhibits relatively low emittance for radiation having a wavelength longer than 1.01 microns and exhibits relatively high emittance for radiation having a wavelength shorter than 1 micron. In some cases, the cutoff wavelength may represent a band of at least 5 nm, at least 10 nm, at least 50 nm, or at least 100 nm. In some cases, the cutoff wavelength may represent a band of no more than 150 nm, no more than 100 nm, no more than 50 nm, or no more than 10 nm. Combinations of the foregoing ranges are possible.

Such optical properties may be useful for efficient power generation using thermophotovoltaic cells. That is, the photonic crystal may primarily emit radiation having a wavelength shorter than the cutoff wavelength, in some cases. In some cases, the cutoff wavelength is equal to or shorter than radiation having energy corresponding to the band gap of a thermophotovoltaic cell. Radiation with a wavelength longer than the band gap of the thermophotovoltaic cell may not be emitted by the photonic crystal, and accordingly may not be lost as waste energy, for example, as heat.

During applications where the photonic crystal is heated to relatively high temperatures, it may be advantageous for the material of the photonic crystal to have a relatively low vapor pressure. For example, in some cases, the vapor pressure of the material of the photonic crystal may be no more than 10⁻⁵ kPa, no more than 10⁻⁶ kPa, no more than 10⁻⁷ kPa, no more than 10⁻⁸ kPa, no more than 10⁻⁹ kPa, or no more than 10⁻¹⁰ kPa. This may be beneficial, for example, when heating the photonic crystal for applications such as thermophotovoltaic power generation because the photonic crystal will not substantially evaporate. In some such applications, the relatively low vapor pressure of the photonic crystal may allow the photonic crystal to operate without degrading (e.g., evaporating) for a relatively long time.

The photonic crystal may have relatively low vapor pressures, in some cases, make it suitable for applications that use relatively high temperatures, for example, thermophotovoltaic power generation. Thus, in certain cases, the photonic crystal may be heated. Due to the optical properties of the photonic crystal, the photonic crystal may be configured to selectively emit radiation. In some such cases, the selected radiation that is emitted from the photonic crystal may pass through the coating and, in some cases, may pass through a region (e.g.., an interior region containing a gas) that may contain water, e.g., as water vapor. For example, the interior region may have a partial pressure of at least 10⁻¹¹ kPa, at least 10⁻¹⁰ kPa, at least 10⁻⁹ kPa, at least 10⁻⁸ kPa, at least 10⁻⁷ kPa, at least 10⁻⁶ kPa, etc. of water vapor. According to some embodiments, the radiation emitted by the photonic crystal may further be directed at a thermophotovoltaic cell, for example, for thermophotovoltaic power generation.

In some cases, the photonic crystal may be heated to temperatures of at least 800°C., at least 900° C., at least 1000° C., at least 1100° C., at least 1200° C., at least 1300° C., at least 1400° C., at least 1500° C., at least 1600° C., at least 1700° C., at least 1800° C., at least 1900° C., or at least 2000° C. In some embodiments, the photonic crystal may be heated to temperatures of no more than 2000° C., no more than 1900° C., no more than 1800° C., no more than 1700° C., no more than 1600° C., no more than 1500° C., no more than 1400° C., no more than 1300° C., no more than 1200° C., no more than 1100° C., no more than 1000° C., no more than 900° C., or no more than 800° C. Combinations of the foregoing ranges are possible.

In some cases, however, the material of the photonic crystal may react when exposed to water vapor. For example, as discussed herein, in photonic crystals comprising tantalum, water vapor may oxidize the tantalum into tantalum hydroxides and/or oxyhydroxides. Tantalum hydroxides and/or oxyhydroxides have relatively high vapor pressures when compared to metallic tantalum, which may lead to the photonic crystal degrading when used for applications such as thermophotovoltaic power generation.

According to some embodiments, after the material of the photonic crystal reacts in the presence of water vapor, the vapor pressure of the photonic crystal may be at least 10⁻⁶ kPa, at least 10⁻⁵ kPa, at least 10⁻⁴ kPa, at least 10⁻³ kPa, at least 10⁻² kPa, at least 10⁻¹ kPa, at least 10⁰ kPa, at least 10¹ kPa, or at least 10² kPa. After reacting in the presence of water vapor, the resulting relatively high vapor pressures of the material of the photonic crystal may be problematic during synthesis, or during use. For example, in some embodiments, when the photonic crystal is heated to relatively high temperatures (e.g., at least 800° C., at least 1000° C., at least 1500° C., at least 2000° C., or other temperature such as those described herein) in the presence of water, hydroxides and/or oxyhydroxides may be formed that have relatively high vapor pressures, and such materials may evaporate, thereby degrading the photonic crystal.

Accordingly, in order to avoid or at least reduce exposing the photonic crystal to the presence of water vapor, a coating may be present on an exposed surface of the photonic crystal. In some cases, the coating on the photonic crystal may have a relatively low vapor pressure, and/or may be relatively inert in the presence of water vapor, and/or may be IR transparent. Moreover, it may be advantageous in certain embodiments for the coatings to have a relatively high melting point, e.g., so that they may be used in certain applications such as thermophotovoltaic power generation without substantially degrading when heated. In some embodiments, the coating on the photonic crystal may prevent or reduce the photonic crystal from being exposed to water vapor, e.g., while also maintaining the optical properties of the photonic crystal.

Any of variety of materials are suitable for use as the coating on the photonic crystal. Non-limiting examples of possible coatings include ceramic materials such as hafnia, zirconia, and/or alumina. For instance, some embodiments are directed to coatings comprising hafnia and/or zirconia. For example, the photonic crystal may comprise tantalum and the coating may comprise hafnia. As another non-limiting example, the photonic crystal may comprise tantalum and the coating may comprise zirconia. In some cases, the coating may comprise at least 50%, at least 60%, at least 70%, at least 80%, at least 90%, at least 95%, at least 99%, etc. (by mass) of a ceramic (e.g., hafnia or zirconia), and/or one or more ceramics (e.g., a combination of hafnia and zirconia).

The coating may be applied to the photonic crystal in any of a variety of methods. Non-limiting examples of suitable methods for depositing the coating include chemical vapor deposition and physical vapor deposition. Other methods are also possible. In some cases, the coating may be applied as a conformal coating, which may maintain the microstructure (e.g., periodicity) of the photonic crystal. In some cases, the coating may be applied to at least a portion of an exposed surface of the photonic crystal, e.g., covering at least 50%, at least 60%, at least 70%, at least 80%, at least 90%, at least 95%, at least 99%, etc. of the surface area of the photonic crystal. In some cases, the coating covers the entire exposed surface of the photonic crystal, such that the photonic crystal may no longer be exposed, for example, to an environment comprising water vapor.

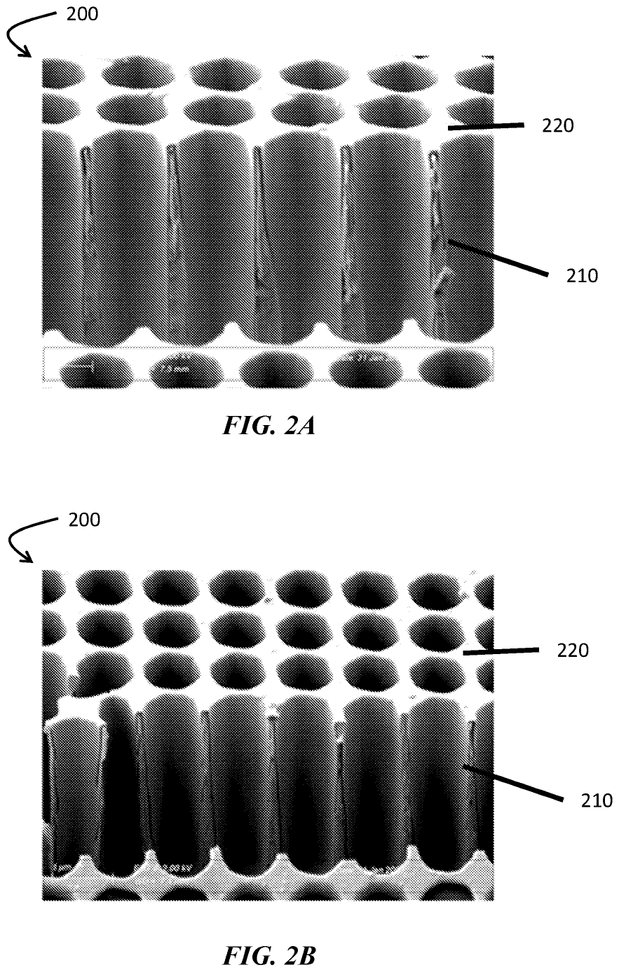

As a non-limiting example of a photonic crystal with a coating, consider FIG. 2A-2B, which are SEM micrographs showing passivated photonic crystals 200. The passivated photonic crystals 200 comprises a photonic crystal 210 comprising tantalum (e.g., the darker material) and a coating 220 comprising hafnia (e.g., the lighter material). The thickness of the coating may be any of a variety of suitable values.

According to some embodiments, the thickness of the coating may be no more than 100 nm, no more than 50 nm, no more than 20 nm, no more than 10 nm, or no more than 1 nm. In some cases, the thickness of the coating may be at least 1 nm, at least 10 nm, at least 20 nm, at least 50 nm, or at least 100 nm. Combinations of the foregoing ranges are possible.

As mentioned above, the coating may cover at least a portion of an exposed surface of the photonic crystal in some cases. According to some embodiments, an exposed surface of the photonic crystal may be a portion of the surface of the photonic crystal that is exposed to a gaseous atmosphere. In some cases, the portion of the photonic in physical contact with the substrate is not exposed to a gaseous atmosphere. Accordingly, in some cases, when the exposed surface of the photonic crystal is covered with the coating, the photonic crystal may no longer has an exposed surface. In accordance with some embodiments, the coating may cover at least 50%, at least 75%, at least 90%, at least 95%, at least 99%, at least 99.9%, or all of an the exposed surface of the photonic crystal, thus making it such that the photonic crystal has a smaller (e.g., or no) surface area of exposed surface than it had before the coating was applied to the photonic crystal.

The material of the coating, in some cases, may have a different index of refraction than the material of the photonic crystal. The index of refraction of the coating may be at least 1.1 times, at least 1.2 times, at least 1.4 times, at least 1.6 times, at least 1.8 times, at least 2 times, or at least 2.5 times higher than what was in contact with the photonic crystal before applying the coating (e.g., air). Accordingly, in some cases, the coating may alter the optical properties exhibited by the photonic crystal, e.g., as compared to a photonic crystal without the coating. One of ordinary skill in the art will understand how to change the dimensions and/or periodicity of the microstructure of the photonic crystal to account for the coating to obtain the desired optical properties.

As described above, the material of the coating may be relatively IR-transparent, e.g., such that radiation emitted by the photonic crystal may be directed through the coating. In some cases, the coating may be one that does not significantly hinder the emittance, for example, by absorbing and/or reflecting the emitted radiation. In some cases, the coating has a transmittance of at least 0.5, at least 0.6, at least 0.7, at least 0.8, at least 0.9, or at least 0.95 of IR radiation (e.g., radiation having a wavelength of at least 700 nm, at least 800 nm, at least 900 nm, at least 1 micron, at least 1.1 microns, at least 1.5 microns, at least 1.8 microns, or at least 2 microns).

In some embodiments, the coating may have a relatively high melting point so that it may be used at relatively high temperatures without degrading, for example, during thermophotovoltaic power generation. In some embodiments, for example, the melting point of the coating is at least 1000° C., at least 1500° C., at least 2000° C., or at least 2500° C.,. In some cases, the melting point of the coating is no more than 3000° C., no more than 2500° C., no more than 2000° C., or no more than 1500° C. Combinations of the foregoing ranges are possible.

In some embodiments, e.g., to avoid or minimize the photonic crystal being exposed to an environment comprising water vapor, the photonic crystal may be present within a vacuum or other interior region before heating the photonic crystal to avoid oxidative degradation (e.g., by reaction with water as described elsewhere herein) of the photonic crystal.

The interior region may contain a vacuum, and/or may contain gases that have very low concentrations of water vapor. One of ordinary skill in the art will understand the meaning of vacuum. In some cases, vacuum indicates a region with a pressure lower than atmospheric or ambient pressure, but the vacuum is not required to be a “perfect” vacuum (i.e., containing zero molecules). For example, according to some embodiments, the vacuum may have a pressure of no more than 10⁻⁴ kPa, no more than 10⁻⁵ kPa, no more than 10⁻⁶ kPa, no more than 10⁻⁷ kPa, no more than 10⁻⁸ kPa, or no more than 10⁻⁹ kPa at room temperature. In some embodiments, the partial pressure of water vapor within the vacuum may be no more than 10⁻⁴ kPa, no more than 10⁻⁵ kPa, no more than 10⁻⁶ kPa, no more than 10⁻⁷ kPa, no more than 10⁻⁸ kPa, or no more than 10⁻⁹ kPa at room temperature, etc.

In some embodiments, when the device is heated relatively high temperatures (e.g., at least 800° C., at least 1000° C., at least 1500° C., at least 2000° C., etc.) the pressure within the interior region may be less than or equal to 10² kPa, less than or equal to 10¹ kPa, less than or equal to 10⁰ kPa, less than or equal to 10⁻¹ kPa, less than or equal to 10⁻² kPa, less than or equal to 10⁻³ kPa, less than or equal to 10⁴ kPa, less than or equal to 10⁻⁵ kPa, or less than or equal to 10⁻⁶ kPa. Additional examples of such devices are described in U.S. Pat. Apl. Ser. No. 63/457,183, entitled “Vacuum Packaging for Photonic Crystals and Methods Thereof,” filed on Apr. 5, 2023, incorporated herein by reference in its entirety.

In some embodiments, a photonic crystal may be positioned on an inner substrate comprising a material that can be heated several hundred degrees without melting or degrading, e.g., heated to a temperature of at least about 1000° C., at least about 1500° C., or at least about 2000° C. In certain embodiments, the inner substrate is a metal. Non-limiting examples of metals include, but are not limited to, aluminum, lead, brass, silver, copper, gold, nickel, iron, steel, or the like. In some embodiments, the inner substrate may be a metal alloy of two or more metals, e.g., including these and/or other metals.

For example, in one set of embodiments, the inner substrate may be an Inconel or another metal superalloy, for example, an austenitic nickel-chromium-based superalloy. Non-limiting examples include Inconel 625, Inconel 617, Inconel 690, Inconel 600, Inconel 718, or Inconel X-750. In some cases, the metal may be an alloy of nickel and chromium, optionally including other metals or materials, such as iron, molybdenum, niobium, tantalum, cobalt, manganese, copper, aluminum, titanium, silicon, carbon, sulfur, phosphorous, boron, etc. According to some embodiments, the inner substrate may comprise at least 90% of a metal superalloy.

According to some embodiments, the article may further comprise a heat source. The heat source, in some cases, may be positioned to heat the inner substrate. In some cases, the inner substrate may be heated chemically, e.g., by burning or reacting a fuel, and the heat that is produced may heat the photonic crystal to emit electromagnetic radiation, which can be directed at a thermophotovoltaic cell to produce power. Non-limiting examples of fuels that can be used include gasoline, ethanol, diesel, petroleum, naphtha, hydrogen, propane, methane, coal gas, water gas, or the like. Additional non-limiting examples of fuel include heavy fuels, such as diesel, jet fuel, kerosene, or the like. Specific non-limiting examples of jet fuel include JP-8, Jet A-1, Jet-A, JP-4, Jet B, TS-1, JP-1, JP-2, JP-3, JP-5, JP-6, JP-7, JP-9, JP-10, JPTS, Zip fuel, syntroleum, or the like.

As described above, when heated, the photonic crystal may selectively emit radiation which may be used to heat a suitable thermal power generator to produce power. For example, a photonic crystal may be heated from the reaction. The photonic crystal may be part of an emitter that emits electromagnetic radiation, which can be directed at a thermophotovoltaic cell to produce power. In some cases, the photonic crystal may emit radiation through the coating, which, according to some embodiments, may comprise hafnia and/or zirconia. In some cases, the photonic crystal is configured to emit radiation that passes through the interior region comprising a gas having at least 10⁻⁹ kPa of water vapor. In some such cases, the thermophotovoltaic cell may be positioned to received radiation emitted from the photonic crystal, for applications such as thermophotovoltaic power generation.

One of ordinary skill in the art will know of suitable thermophotovoltaic cells. It may be advantageous to select a photonic crystal that emits radiation having a wavelength that is greater than or equal to radiation that can be absorbed by the thermophotovoltaic cell (e.g., matching the emittance of the photonic cell with the band gap of the thermophotovoltaic cell). In this manner, little-to-no radiation emitted by the photonic crystal is lost as heat due to the thermophotovoltaic cell being unable to absorb the radiation.

In a preferred set of embodiments, the substrate comprises an IR transparent material and defines an interior region, the interior region comprising a gas containing at least 10⁻⁹ kPa of water vapor. In some embodiments, the IR transparent material comprises sapphire and/or quartz. In some cases, a photonic crystal comprising tantalum may be positioned at least partially within the interior region of the substrate, and the photonic crystal may be at least partially coated with a coating. The coating, in accordance with some embodiments, may be hafnia. In some cases, the coating may be zirconia. In some embodiments, the coating may separate the photonic crystal from contacting the water vapor in the gas. In some cases, the photonic crystal may be heated. In some such cases, the photonic crystal may emit radiation through the coating and through the interior region comprising the gas. In some such cases, the coating may comprises hafnia and/or zirconia.

U.S. Pat. Apl. Ser. No. 63/339,617, entitled “Rapid Mixing Systems and Methods for Fuel Burners,” filed May 9, 2022, is incorporated herein by reference in its entirety. In addition, U.S. Pat. Apl. Ser. No. 63/457,176, entitled “Systems and Methods for Photonic Crystal Integration,” and U.S. Pat. Apl. Ser. No. 63/457,183, entitled “Vacuum Packaging for Photonic Crystals and Methods Thereof,” each filed on Apr. 5, 2023, are also each incorporated herein by reference in its entirety. Also, U.S. Pat. Apl. Ser. No. 63/457,179, filed Apr. 5, 2023, entitled “Passivation Systems and Methods for Photonic Crystals,” is incorporated herein by reference in its entirety.

The following examples are intended to illustrate certain embodiments of the present invention, but do not exemplify the full scope of the invention.

### EXAMPLE 1

The following is an example of coatings on a photonic crystal. Two samples were prepared in this example. First, a photonic crystal comprising tantalum was prepared. Second, a photonic crystal of substantially the same composition as the first sample was prepared, but then the photonic crystal was coated with a 20 nm coating of hafnia deposited by atomic layer deposition.

The first sample was then placed in a chamber and heated via induction to 1000° C. for approximately 1 minute. During the heating process, the chamber also contained a ceramic washer. After heating the first sample, deposits of tantalum compounds were observed on the ceramic washer, indicating the tantalum of the first sample evaporated and redeposited on the ceramic washer. Subsequently, the second sample was placed in the chamber with a ceramic washer. The second sample was also heated via induction to 1000° C. for approximately 1 minute. In the case of the second sample, after heating, no deposits were observed on the ceramic washer, indicating the passivated photonic crystal was stable (e.g., did not substantively evaporate).

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used.

Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein, “wt %” is an abbreviation of weight percentage. As used herein, “at %” is an abbreviation of atomic percentage.

Some embodiments may be embodied as a method, of which various examples have been described. The acts performed as part of the methods may be ordered in any suitable way. Accordingly, embodiments may be constructed in which acts are performed in an order different than illustrated, which may include different (e.g., more or less) acts than those that are described, and/or that may involve performing some acts simultaneously, even though the acts are shown as being performed sequentially in the embodiments specifically described above.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. An article, comprising:
a substrate comprising an IR-transparent material and defining an interior region comprising a gas containing at least 10⁻⁹ kPa of water vapor;
a photonic crystal comprising tantalum, the photonic crystal being positioned at least partially within the interior region of the substrate; and
a coating comprising hafnia or alumina, wherein the coating separates the water vapor in the gas from contact with the photonic crystal.

2. The article of claim 1, wherein the substrate comprises sapphire.

3. The article of any one of claims 1 or 2, wherein the photonic crystal is positioned entirely within the interior region of the substrate.

4. The article of any one of claims 1-3, wherein an average thickness of the coating is at least 20 nm.

5. The article of any one of claims 1-4, further comprising an inner substrate in physical contact with the photonic crystal.

6. The article of any one of claims 1-5, wherein the photonic crystal positioned to emit radiation through the coating and the interior region.

7. The article of any one of claims 1-6, wherein the substrate further defines an exterior region.

8. The article of claim 7, further comprising a thermophotovoltaic cell in the exterior region and positioned to receive radiation emitted from the photonic crystal. The article of any one of claims 1-8, wherein a vapor pressure of the coating is less than or equal to 10⁻⁵ kPa.

10. The article of any one of claims 1-9, wherein the photonic crystal further comprises a second refractory metal.

11. The article of any one of claims 1-10, wherein the photonic crystal further comprises tungsten.

12. The article of any one of claims 1-11, wherein the substrate comprises quartz.

13. An article, comprising:
a photonic crystal comprising tantalum; and
a coating comprising zirconia at least partially covering the tantalum.

14. The article of claim 13, wherein the photonic crystal is present in a region having a pressure less than or equal to 10⁻⁴ kPa.

15. The article of any one of claims 13 or 14, further comprising a substrate comprising an IR-transparent material and defining an interior region comprising a gas containing at least 10⁻⁹ kPa of water vapor, wherein the photonic crystal is positioned at least partially within the interior region of the substrate.

16. The article of any one of claims 13-15, wherein the substrate comprises sapphire.

17. The article of any one of claims 13-16, wherein the photonic crystal is positioned entirely within the interior region of the substrate.

18. The article of any one of claims 13-17, wherein an average thickness of the coating is at least 20 nm.

19. The article of any one of claims 13-18, further comprising an inner substrate in physical contact with the photonic crystal. The article of any one of claims 13-19, wherein the photonic crystal positioned to emit radiation through the coating and the interior region.

21. The article of any one of claims 13-20, wherein the substrate further defines an exterior region.

22. The article of claim 21, further comprising a thermophotovoltaic cell in the exterior region and positioned to receive radiation emitted from the photonic crystal.

23. The article of any one of claims 13-22, wherein a vapor pressure of the coating is less than or equal to 10⁻⁵ kPa.

24. The article of any one of claims 13-23, wherein the photonic crystal further comprises a second refractory metal.

25. The article of any one of claims 13-24, wherein the photonic crystal further comprises tungsten.

26. A method, comprising:
emitting radiation from a photonic crystal;
passing the radiation through zirconia, hafnia, or alumina; and
passing the radiation through a region having a gas containing at least 10⁻⁹ kPa of water vapor.

27. The method of claim 26, further comprising using a thermophotovoltaic cell to convert at least a portion of the radiation into electricity.

28. The method of any one of claim 26 or 27, further comprising heating the photonic crystal.

29. The method of claim 28, further comprising heating the photonic crystal using an Inconel burner tube.

30. The method of any one of 26-29, wherein the zirconia, hafnia, or alumina are present as a coating on at least a portion of the photonic crystal.

31. The method of claim 30, wherein the coating covers substantially all of an exposed surface of the photonic crystal.

32. The method of any one of claims 30 or 31, wherein the coating separates the photonic crystal from the region having the gas.

33. The method of any one of claims 26-32, further comprising a substrate comprising an IR transparent material, the substrate defining the region having the gas.

34. The method of claim 33, wherein the substrate comprises sapphire.

35. A method, comprising:
emitting radiation from a photonic crystal;
passing the radiation through a coating positioned on the photonic crystal; and
passing the radiation through a region having a gas containing at least 10⁻⁹ kPa of water vapor,
wherein the coating separates the water vapor in the gas from contact with the photonic crystal.
